(19) United States
(12) Patent Application Publication
(10) Pub. No.: US 2009/0290319 A1
(43) Pub. Date: Nov. 26, 2009

(54) ELECTROMAGNETIC SHIELDING IN SMALL-FORM-FACTOR DEVICE

(75) Inventors: Scott A. Myers, San Francisco, CA (US); Peter J. Hues, San Jose, CA (US); Erik L. Wang, Redwood City, CA (US)

Correspondence Address: ROPES & GRAY LLP, PATENT DOCKETING 39/361, 1211 AVENUE OF THE AMERICAS, NEW YORK, NY, 10036-8704, US

(73) Assignee: APPLE INC., Cupertino, CA (US)

(21) Appl. No.: 12/123,976

(22) Filed: May 20, 2008

(51) Int. Cl. H05K 9/00

(52) U.S. Cl. 361/818

(57) ABSTRACT

In a device having a circuit board bearing one or more components requiring electromagnetic shielding, and having a subassembly with a conductive backplane, the circuit board is mounted beneath that backplane. Each component or group of components requiring shielding is surrounded by a grounded shielding can having an open top. Conductive spring fingers, aligned with the walls of the can, are formed in or on the backplane. When the device is assembled, the backplane closes the can. The spring fingers press against, or interengage with, the tops of the can walls, electrically bridging any gap resulting from assembly tolerances.

### BACKGROUND OF THE INVENTION

This invention relates to arrangements for providing shielding against electromagnetic interference for components of an electronic device having a small form factor.

There are many devices, particularly hand-held electronic devices, which it may be desirable to provide in a housing having a small form factor. Nevertheless, that housing must contain a large number of components, including electronic circuitry for performing the function of the device, as well as user interface components such as buttons or other controls, acoustic transducers such as speakers and/or microphones, visual indicators such as light-emitting diodes (LEDs), and/or a display screen which also may function as a touch input device.

Some of the aforementioned components may require shielding against electromagnetic interference. For example, the electronic circuitry for performing the function of the device may include a circuit board having various components mounted thereon, some of which require shielding. A common way of providing such shielding is to mount a “can”—i.e., a metallic enclosure which may be round, rectangular or of any other shape, and which is closed off at the top—on the circuit board surrounding the component to be shielded. The can is then electrically connected—e.g., by soldering—to a ground conductor on the circuit board. The interior height of the can must be sufficient to clear the component being shielded, while the overall height of the can necessarily exceeds the interior height by the thickness of the top closure of the can. While the thickness of the metal from which the can is formed may be on the order of only thousandths of an inch (i.e., tens of microns), that thickness may noticeably increase the form factor of the overall device.

### SUMMARY OF THE INVENTION

In accordance with the present invention, in a small-form-factor device having a circuit board bearing one or more components that require shielding against electromagnetic interference, and having a component, such as a display module, keypad module, etc., that has a conductive backplane, the circuit board is mounted beneath that conductive backplane.

Each component or group of components on the circuit board that requires shielding may be surrounded by a grounded shielding can having an open top. The conductive backplane closes the top of the can. The conductive backplane has to be in electrical contact with the walls of the can to complete the shielding. This may be accomplished by forming, in or on the conductive backplane, conductive spring fingers aligned with the walls of the can. When the device is assembled, the spring fingers press against, or interengage with, the tops of the can walls, electrically bridging any gap resulting from assembly tolerances between the conductive backplane and the can walls. The spring fingers may be formed separately—e.g., on separate metallic strips—and then fastened to the conductive backplane, or they may be stamped from the backplane itself.

Therefore, in accordance with the present invention, there is provided a device including a subassembly having a conductive backplane, and a circuit board having components thereon and being mounted relative to the subassembly such that the components are between the circuit board and the conductive backplane. For each of at least one of the components, a shielding wall surrounds that at least one of the components, and extends from the circuit board toward the conductive backplane, and a yielding conductive element extends from the conductive backplane toward the circuit board, to conductively fill any gap between the shielding wall and the conductive backplane.

A method shielding components of a device also is provided.

### BRIEF DESCRIPTION OF THE DRAWINGS

Further features of the invention, its nature and various advantages, will be apparent upon consideration of the following detailed description, taken in conjunction with the accompanying drawings, in which like reference characters refer to like parts throughout, and in which:

FIG. 1 is a cross-sectional view of an exemplary device with which the present invention may be used;

FIG. 2 is an exploded perspective view of a circuit board and conductive backplane of the device of FIG. 1 incorporating an embodiment of the invention;

FIG. 3 is a perspective view of the backplane of FIG. 2, taken from line 3-3 of FIG. 2; and

FIG. 4 is a fragmentary, partially cross-sectional view of a portion of the embodiment of FIGS. 2 and 3.

### DETAILED DESCRIPTION

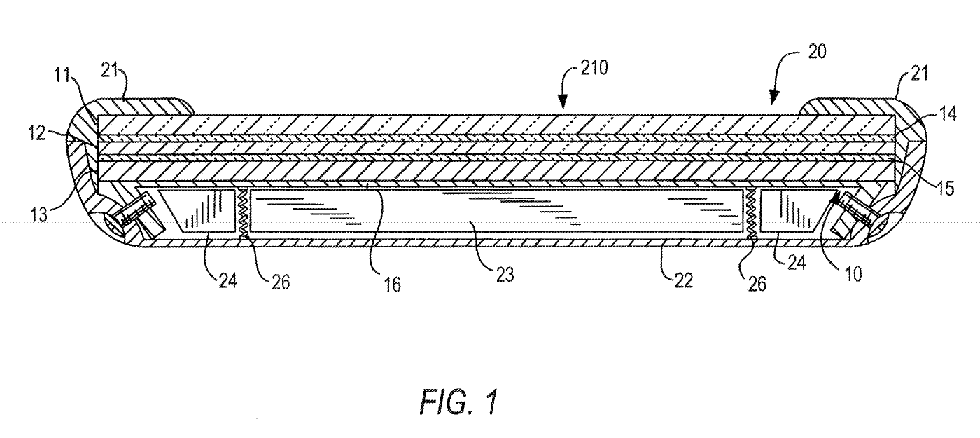

The present invention may be used in a device 20 such as that shown in FIG. 1. As can be seen, device 20 includes a bezel 21 having a window opening 210 into which display window assembly 10 is mounted, as well as rear or lower housing 22 to which bezel 21 is attached by any suitable attachment method (not shown). Housing 22 may house functional component or components 23, as well as body mass or masses 24. Resilient element or elements 26 may be provided to urge display window assembly 10 outward of bezel 21. Although the particular structure of display window assembly 10 is not important to the present invention, display window assembly 10 may include a window layer 11, a touch-sensitive layer 12, and a display layer 13. Layers 11 and 12, and layers 12 and 13, may be bonded to one another by respective transparent bonding layers 14, 15. A frame or support 16 may be affixed to display window assembly 10 beneath display layer 13. Frame or support 16 may be affixed to the underside of display layer 13, as by a suitable adhesive (not shown), or may be formed (not shown) around the edges of display window assembly 10 or around the edges of one or more of its layers 11, 12, 13. Frame or support 16 may be made from any suitable conductive material, such as stainless steel or other metallic material, although a conductive polymeric material (e.g., a polymeric material impregnated with conductive particles) may be used, whereby frame or support 16 functions as a conductive backplane for display window assembly 10.

As discussed above, functional components 23 may include one or more components requiring shielding against electromagnetic interference. In accordance with the present invention, that shielding may be provided using frame or support 16 as one wall of a shielding “can” for each component requiring shielding. Specifically, functional components 23 may include a printed circuit board having various electrical components thereon, one or more of which may require shielding against electromagnetic interference to function properly.

In an exemplary embodiment, the walls of the shielding can are mounted on, and grounded to, the printed circuit board, while frame or support 16 forms the roof of the shielding can once device 20 has been assembled. In this embodiment, a yielding conductive element is provided to assure that, notwithstanding any gaps caused by assembly tolerances, there is effective electrical contact between the can walls and frame or support 16.

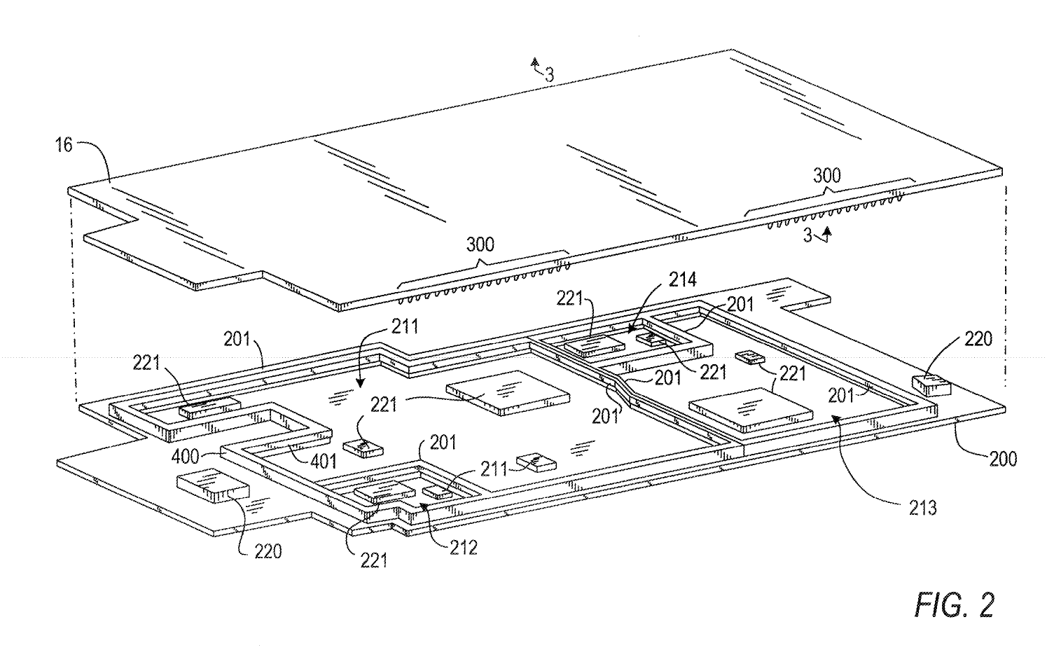

An example of this embodiment is shown in FIGS. 2-4. Circuit board 200 has a plurality of components mounted thereon, some of which require shielding against electromagnetic interference. As shown, a plurality of conductive walls 201 are provided on circuit board 200, dividing circuit board 200 into a plurality of areas 211, 212, 213, 214. Circuit components 220, outside all of those areas, are examples of components that do not need shielding. Conversely, components 221 inside the various shielded areas are examples of components that do need shielding. As there are multiple components 221 within the various areas 211, 212, 213, 214, it is apparent that some of components 221 that require shielding do not require shielding from each other, but do require shielding from others of components 221, from components 220, or from outside sources of interference. In addition, there may be other components (not shown) in the various areas 211, 212, 213, 214 that do not themselves require shielding, but from which certain of components 221 do require shielding. Thus, those certain components 221 would be located in a different one of areas 211, 212, 213, 214 from the unseen components from which they require shielding. Finally, some components 221 may not themselves be susceptible to electromagnetic interference, but may be sources of such interference and therefore require shielding to comply with government regulations and/or industry standards regarding emission of interference.

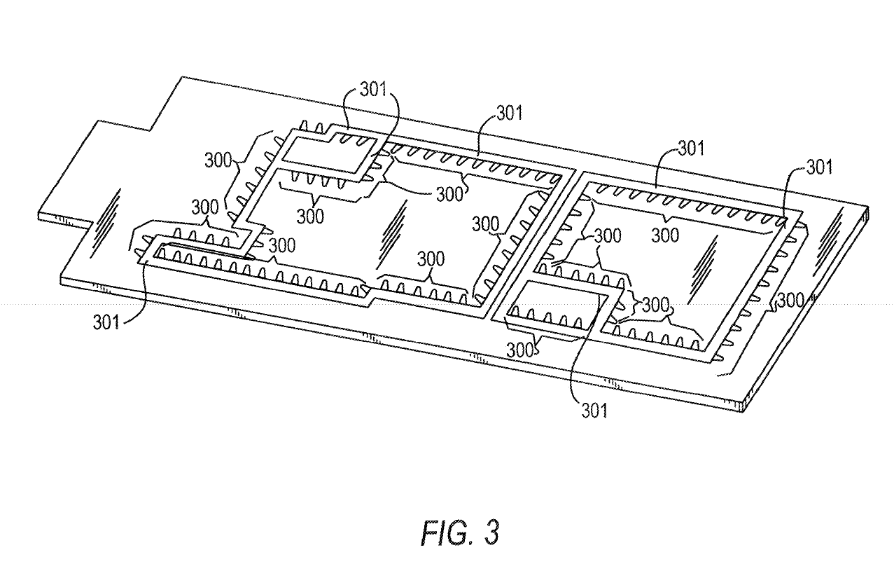

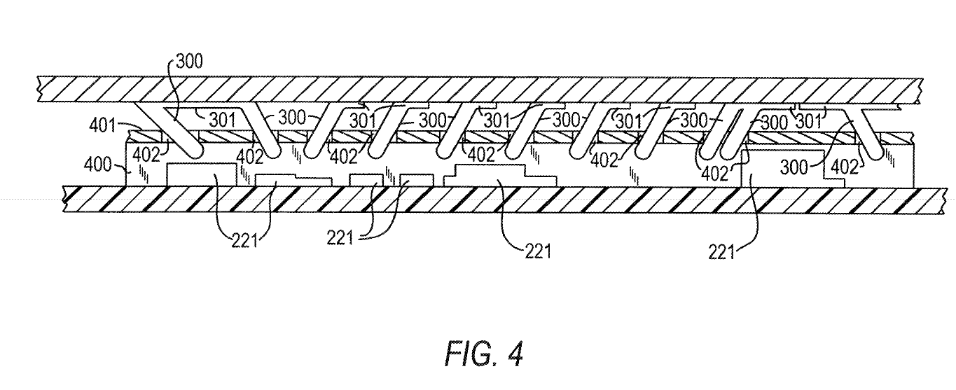

Spring fingers 300 depend from the underside of conductive backplane 16, as seen most clearly in FIGS. 3 and 4. As shown in FIG. 3, spring fingers 300 are formed on strips 301, which may then be attached to conductive backplane 16 by any conductive attachment, such as soldering, welding or riveting. Alternatively, however, spring fingers 300 may be stamped directly (not shown) from backplane 16, provided that the resulting holes in backplane 16 have no detrimental effects on assembly 10.

As best seen in FIG. 4, conductive walls 201 have upstanding portions 400 as well as, preferably, horizontal flanges 401 with slots 402 therein. On assembly of device 20, spring fingers 300 are mated to slots 402. The elastic nature of spring fingers 300 causes a restoring force that results in good electrical contact with the sides of slots 402, making backplane 16 part of the shielding. Alternatively, slots 402 could be omitted (not shown), and spring fingers 300 could rest directly on flanges 401, with the spring force pressing downward to maintain contact. In a further alternative (not shown), flanges 401 also could be omitted, and spring fingers 300 could rest directly on the top edges of upstanding portions 400, with the spring force pressing downward to maintain contact.

Thus it is seen that shielding components in a small-form-factor device, without unnecessarily increasing the thickness of the device, has been provided. It will be understood that the foregoing is only illustrative of the principles of the invention, and that various modifications can be made by those skilled in the art without departing from the scope and spirit of the invention, and the present invention is limited only by the claims that follow.

What is claimed is:

1. A device comprising:
a subassembly having a conductive backplane;
a circuit board having components thereon and being mounted relative to said subassembly such that said components are between said circuit board and said conductive backplane; and
for each of at least one of said components:
a shielding wall surrounding said at least one of said components, and extending from said circuit board toward said conductive backplane, and
a yielding conductive element extending from said conductive backplane toward said circuit board, to conductively fill any gap between said shielding wall and said conductive backplane.

2. The device of claim 1 wherein said yielding conductive element comprises at least one spring element extending from said conductive backplane.

3. The device of claim 2 wherein:
said shielding wall has therein a respective opening corresponding to each said at least one spring element; and
each said at least one spring element interengages said respective opening.

4. The device of claim 2 wherein:
said at least one spring element comprises at least one conductive strip, each said at least one conductive strip having one said at least one spring element extending therefrom; and
each said at least one strip is fastened to said conductive backplane.

5. The device of claim 4 wherein each said at least one strip is soldered to said conductive backplane.

6. The device of claim 4 wherein each said at least one strip is welded to said conductive backplane.

7. The device of claim 4 wherein each said at least one strip is riveted to said conductive backplane.

8. The device of claim 1 wherein:
said yielding conductive element comprises at least one conductive strip, each said at least one conductive strip having at least one said yielding conductive element extending therefrom; and
each said at least one strip is fastened to said conductive backplane.

9. The device of claim 8 wherein each said at least one strip is soldered to said conductive backplane.

10. The device of claim 8 wherein each said at least one strip is welded to said conductive backplane.

11. The device of claim 8 wherein each said at least one strip is riveted to said conductive backplane.

12. A method of shielding at least one component of a device, said device having a subassembly with a conductive backplane, and a circuit board having said at least one component thereon; said method comprising:
forming on said circuit board a respective shielding wall surrounding each said at least one component;
forming on said conductive backplane a respective yielding conductive element extending from said conductive backplane at a location corresponding to each said respective shielding wall; and
assembling said circuit board adjacent said subassembly with said at least one component being located between said circuit board and said conductive backplane; wherein:
each said respective shielding wall contacts said yielding conductive element to conductively fill any gap between said shielding wall and said conductive backplane.

13. The method of claim 12 wherein said forming on said conductive backplane a respective yielding conductive element comprises forming at least one spring element extending from said conductive backplane.

14. The method of claim 13 wherein:
said forming on said circuit board a respective shielding wall surrounding each said at least one component comprises forming a respective slot in said shielding wall corresponding to each said at least one spring element; and
said assembling comprises interengaging each said at least one spring element with said respective slot.

15. The method of claim 13 wherein said forming at least one spring element extending from said conductive backplane comprises:
forming at least one conductive strip, each said at least one conductive strip having one said at least one spring element extending therefrom; and
fastening each said at least one strip to said conductive backplane.

16. The method of claim 15 wherein said fastening comprises soldering.

17. The method of claim 15 wherein said fastening comprises welding.

18. The method of claim 15 wherein said fastening comprises riveting.

19. The method of claim 12 wherein forming on said conductive backplane a respective yielding conductive element comprises:
forming at least one conductive strip, each said at least one conductive strip having at least one said yielding conductive element extending therefrom; and
fastening each said at least one strip to said conductive backplane.

20. The method of claim 19 wherein said fastening comprises soldering.

21. The method of claim 19 wherein said fastening comprises welding.

22. The method of claim 19 wherein said fastening comprises riveting.
